(19) United States
(12) Patent Application Publication
(10) Pub. No.: US 2008/0217051 A1
(43) Pub. Date: Sep. 11, 2008

(54) WIRING BOARD AND METHOD OF MANUFACTURING WIRING BOARD

(75) Inventor: Akiko MATSUI, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU LIMITED, Kawasaki (JP)

(21) Appl. No.: 12/042,788

(22) Filed: Mar. 5, 2008

(30) Foreign Application Priority Data
Mar. 7, 2007 (JP) 2007-057826

(51) Int. Cl. H05K 1/11; H05K 3/42

(52) U.S. Cl. 174/266; 29/852

(57) ABSTRACT

A wiring board including a plated through hole provided on the wiring board, and an indicator provided around the plated through hole. The indicator indicating a processing state related to the plated through hole.

### CROSS REFERENCE TO RELATED APPLICATIONS

This application is related to and claims priority to Japanese Patent Application No. JP2007-057826 filed on Jul. 3, 2007 in the Japan Patent Office, and incorporated by reference herein.

### BACKGROUND

1. Field

The embodiment relates to a wiring board. The embodiment is favorably adapted to a wiring board having a plated through hole connected to a conductive layer including a signal wiring.

2. Description of the Related Art

A multi-layer wiring board is employed as a wiring board so as to form a high-frequency circuit and a high-speed digital circuit and the like. The multi-layer wiring board includes a plated through hole so as to pull out the conductive layer including the signal wiring formed in the multi-layer wiring board to the surface of the board.

In FIG. 1, a wiring board 1 is a multi-layer wiring board. A signal wiring 2 is formed with a conductive layer formed in the multi-layer wiring board. A plated thorough hole 3 is formed so as to be electrically connected to the signal wiring 2 in the wiring board 1. The plated through hole 3 is formed by plating a conductive material such as copper onto the inner wall of a non-plated through hole.

The signal wiring 2 is electrically connected to the plated through hole 3 by connecting to the plated through hole 3 near the center of the plated through hole 3. The plated through hole 3 is formed in the wiring board 1 so as to pull out the signal wiring 2 to the surface of the wiring board 1. An electronic signal is provided from the surface of the plated through hole 3, and is transmitted to the signal wiring 2 near the center of the plated through hole 3. The part where the signal wiring 2 is connected becomes a branch point of signal paths because the plated through hole 3 is extended below the part where the signal wiring 2 is connected.

Signals transmitted through the plated through hole 3 are transmitted to the signal wiring 2 from the branch point, and some of the signals are also transmitted down below the plated through hole 3. The downside of the branch point in the plated through hole 3 is a path in which signals are transmitted because the downside of the branch point is a conductive part, even though the downside of the branch point is not a signal path. As described above, in case a signal path is branched into two, the part which is not an original signal path is referred to as “stub”.

A signal transmitted to a stub from the branch point is reflected at the bottom of the plated through hole 3, and is then returned to the branch point. At that time, the signal transmitting from the branch point hits the reflected signal in the plated through hole. This may adversely affect a transmission characteristic of the signals. For example, signals such as high-frequency signals and high-speed digital signals are affected significantly.

For example, Japanese Laid-open Patent Publication No. 2005-116945 is known as a method for removing a stub. Japanese Laid-open Patent Publication No. 2005-116945 discloses a technology for removing a plated through hole and a board nearby by drilling. Such technology may be referred to as “back-drilled method” or “stub countersunk method”.

In the back-drilled method shown in FIGS. 2A-2C, the part where the plated through hole 3 is formed is removed with a drill 4 whose diameter is slightly bigger than the diameter of the plated through hole 3. As a result, the part corresponding to a stub in the plated through hole 3 is removed. The hole formed with the drill 4 is referred to as “back-drilled hole”. FIG. 2A shows that the plated through hole 3 is formed. FIG. 2B shows the process of drilling the plated through hole 3 with the drill 4. FIG. 2C shows that a back-drilled hole 5 is formed by drilling the plated through hole 3.

However, if the central axis of the drill is positioned out of the central axis of the plated through hole, there is possibility that the part corresponding to a stub in the plated through hole remains even after the back-drilled processing. By checking the back-drilled hole visually, it is possible to determine whether or not the part corresponding to a stub in the plated through hole is completely removed. However, the determination is not made easily if the diameter of the plated through hole is small.

### SUMMARY

It is an object of the embodiment to at least partially solve the problem in the conventional technology.

According to an aspect of an embodiment, a wiring board, comprising: a plated through hole provided on the wiring board; and an indicator provided around the plated through hole, indicating a processing state related to the plated through hole.

According to another aspect of the embodiment, a method of manufacturing a wiring board, the method comprising: forming a plated through hole in the board; forming an indicator around the plated through hole on a surface of the board, the indicator can be checked visually; and removing a part of the plated through hole in the indicator together with the board nearby, for forming a processing hole.

The above and other object, features, advantages and technical and industrial significance of this embodiment will be better understood by reading the following detailed description of presently preferred embodiments, when considered in connection with the accompanying drawings.

### BRIEF DESCRIPTION OF THE DRAWINGS

FIG. 1 is a cross-section diagram of a wiring board in which a plated through hole is formed.

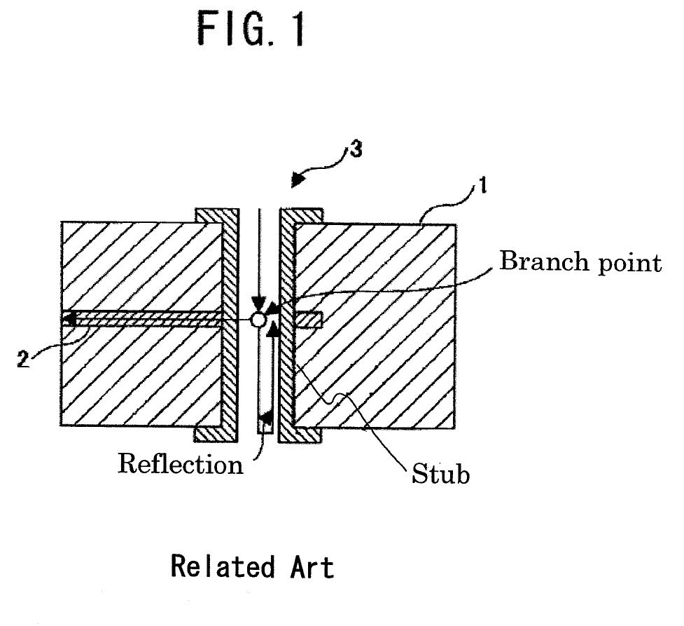

FIG. 2A, FIG. 2B and FIG. 2C are diagrams showing a back-drilled method.

FIG. 3 is a cross-section perspective view of a wiring board.

FIG. 4 is a wiring board which is given a marking according to a first embodiment.

FIG. 5A and FIG. 5B are diagrams showing a position of a back-drilled hole according to a first embodiment.

FIG. 6A, FIG. 6B and FIG. 6C are diagrams showing a process of marking formation.

FIG. 7 is a diagram showing that a land is entirely covered with a marking.

FIG. 8 is a wiring board which is given marking according to a second embodiment.

FIG. 9A and FIG. 9B are diagrams showing a position of a back-drilled hole according to a second embodiment.

FIG. 10A and FIG. 10B are diagrams showing deformation examples of marking.

FIG. 11 is a wiring board in which a land is formed according to a third embodiment.

FIG. 12A and FIG. 12B are diagrams showing a position of a back-drilled hole according to a third embodiment.

### DETAILED DESCRIPTION OF THE PREFERRED EMBODIMENTS

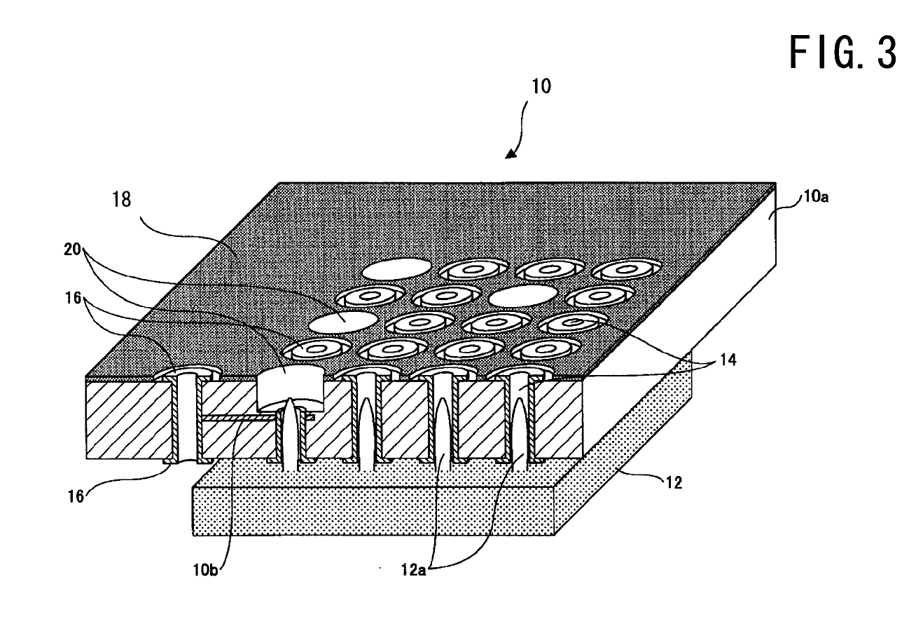

A wiring board of the present embodiment is explained using FIG. 3. FIG. 3 discloses that an electronic component 12 is loaded on a mounting surface of a wiring board 10. The wiring board 10 is comprised of a multi-layer wiring board 10a formed by laminating plastic such as glass epoxy and polyimide. A terminal 12a of the electronic component 12 is inserted into a plated through hole 14 formed in the multi-layer wiring board 10a, and is connected to the plated through hole 14 with an electrically conductive adhesive such as a solder. In the multi-layer wiring board 10a, a signal wiring 10b is formed and connected to the plated through hole 14.

The plated through hole 14 is formed by plating a conductive material, such as copper, onto the inner wall of a non-plated through hole formed in the multi-layer wiring board 10a.

A land 16 whose diameter is slightly bigger than the diameter of the plated through hole 14 is formed at both ends of the plated through hole 14. The land 16 is formed both on the mounting surface and the back surface of the wiring board 10, and the plating processing of the plated through hole 14 is performed at the same time.

A solder resist 18 is applied to the back surface of the multi-layer wiring board 10a, leaving the part where the land 16 is exposed. A back-drilled hole 20 is formed so as to remove the part corresponding to a stub in the plated through hole 14 to which the high-frequency signal is transmitted.

Next, a first embodiment is explained. According to the first embodiment, a marking is printed in the area where a back-drilled hole should be formed. The marking is surrounded by a solder resist 18 and has an annulus ring shape with a highlighted color.

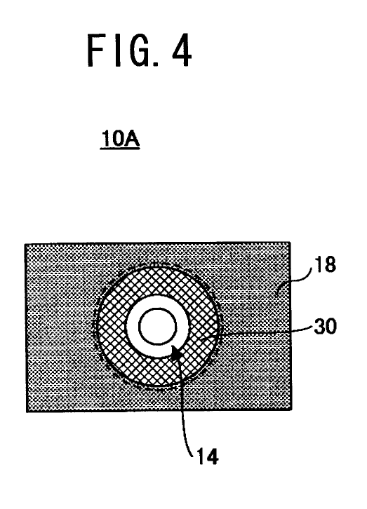

FIG. 4 discloses that a marking 30 having an annulus ring shape is printed in the area where the back-drilled hole 20 should be formed. The marking 30 operating as an indicator is provided to check visually the position of the back-drilled hole 20 after the back-drilled hole 20 is formed. In FIG. 4, the inside of the dotted line circle is the area where the back-drilled hole 20 should be formed. This area is referred to as “countersunk area”. The dotted line circle showing the countersunk area is presented to explain the present embodiment for convenience sake. Thus, the dotted line circle is actually not drawn on top of the wiring board 10A. The dotted line circle showing the countersunk area has almost the same shape as the external diameter of the back-drilled hole 20. However, the presented dotted line circle is slightly bigger than the external diameter of the back-drilled hole 20 for convenience sake of drawing.

The marking 30 is a printed part having an annulus ring shape whose external diameter is slightly smaller than the countersunk area and whose inner diameter is bigger than the inner diameter of the plated through hole 14. The marking 30 is an indicator in which coloring materials such as color ink and colored resin are printed into an annulus ring shaped pattern included in the countersunk area.

The solder resist 18 is applied to the surrounding area of the marking 30. The solder resist 18 is generally dark green. It is preferable that the marking 30 is white or deep light blue so as to be visually distinguishable from the color of the solder resist 18.

The marking 30, for example, can be formed by printing white ink or deep light blue ink into a pattern of an annulus ring shape using a silk-screen printmaking process. For example, the marking 30 can also be formed by ink-jet producing a jet ink which is broken into droplets of coloring materials.

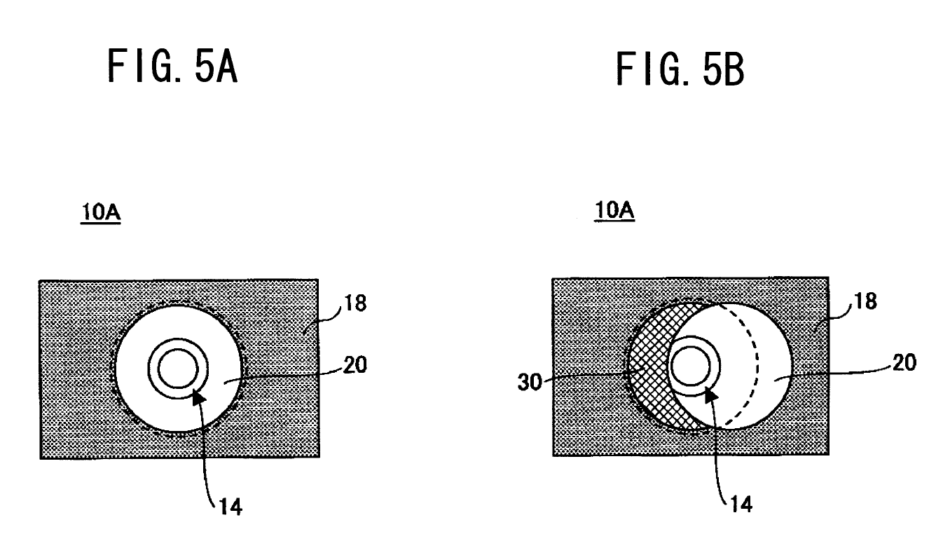

The back-drilled hole 20 is formed after the marking 30 is formed as an indicator. Thus, the part of the plated through hole 14, that is, the part corresponding to a stub, is removed. The external diameter of the marking 30 is set to the same as that of the back-drilled hole 20 or is set to be slightly smaller than that of the back-drilled hole 20. Therefore, when forming the back-drilled hole 20, if the drill is correctly positioned at the countersunk area, that is, if the drill is positioned with accuracy and the position of the back-drilled hole 20 is not out of the countersunk area, the marking 30 is entirely removed with the drill. Therefore, the marking 30 is removed and cannot be seen after the back-drilled hole 20 is formed. This state is shown in FIG. 5A. The dotted line circle in FIG. 5A shows the countersunk area. The dotted line circle in FIG. 5B also shows the countersunk area.

On the other hand, when the drill is positioned with less accuracy and the position of the back-drilled hole 20 is considerably out of the countersunk area, a part of the marking 30 remains unremoved as shown in FIG. 5B. In FIG. 5B, a part of the plated through hole 14 seen at the bottom of the back-drilled hole 20 is out of the back-drilled hole 20. The part outside of the plated through hole 14 remains unremoved. This state shows that the stub is not removed completely, and is referred to as “bad back-drill”. It is possible to determine that a bad back-drill occurs whereat if the marking 30 remains after the back-drilled hole 20 is formed. It is possible to check easily and visually whether or not the marking 30 remains, or how much of the marking 30 remains because the marking 30 is formed in a color having a high level of visibility.

It is preferable to decide on an external diameter of the marking 30 in consideration of the external diameter of the plated through hole 14. That is, it is preferable to decide on an external diameter of the marking 30 so as to check visually the remaining part of the marking 30 when the back-drilled hole 20 is out of the desired position, and the external diameter of the back-drilled hole 20 does not exceed the external diameter of the plated through hole 14. If the external diameter of the marking 30 is too small, the visibility of the marking 30 is low even if the part of the plated through hole 14 remains. On the contrary, if the external diameter of the marking 30 is too big, the remaining part of the marking 30 is big and the visibility of the marking 30 is too high if the back-drilled hole 20 is slightly out of the desired position. Thus, the misalignment of the plated through hole 20 may be considered a bad back-drill by mistake, even though the misalignment of the plated through hole 20 is within the accepted range.

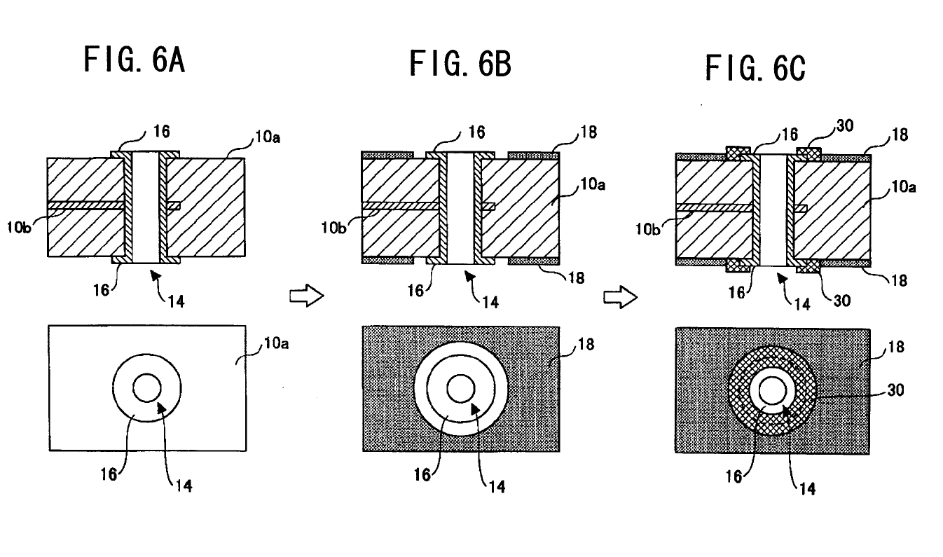

Next, a method of forming the marking 30 is explained using FIG. 6. FIG. 6A discloses that the plated through hole 14 is formed in the multi-layer wiring board 10a. In this case, the land 16 and the plated through hole 14 are formed at the same time. In FIG. 6A, the top surface of the multi-layer wiring board 10a corresponds to the back surface of the wiring board 10A, and the upside of the signal wiring 10b in the plated through hole 14 is targeted to be removed as a stub.

FIG. 6B discloses that the solder resist 18 is applied to the back surface of the multi-layer wiring board 10a after the plated through hole 14 is formed in the multi-layer wiring board 10a. The solder resist 18 is applied to slightly cover outside of the circumference of the land 16, so that the land 16 surrounding the plated through hole 14 is exposed. The solder resist is also applied to the mounting surface, i.e., the top surface, of the multi-layer wiring board 10a.

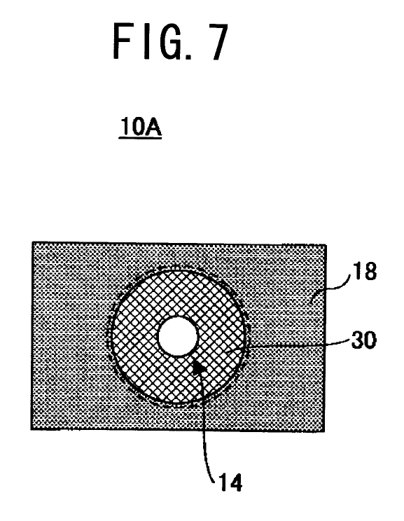

FIG. 6C discloses that the marking 30 is printed by a silk-screen printmaking process. According to the present embodiment, the marking 30 is formed to nearly cover the center of the land 16 having an annulus ring shape in the radial direction. As shown in FIG. 7, it is preferable to nearly cover the center of the land 16 when the marking 30 covers the land 16 entirely. This is because the plated through hole 14 may be adversely affected if a material of the marking 30 comes inside the plated through hole 14. The marking 30 can be formed by ink-jet other than the silk-screen printmaking process.

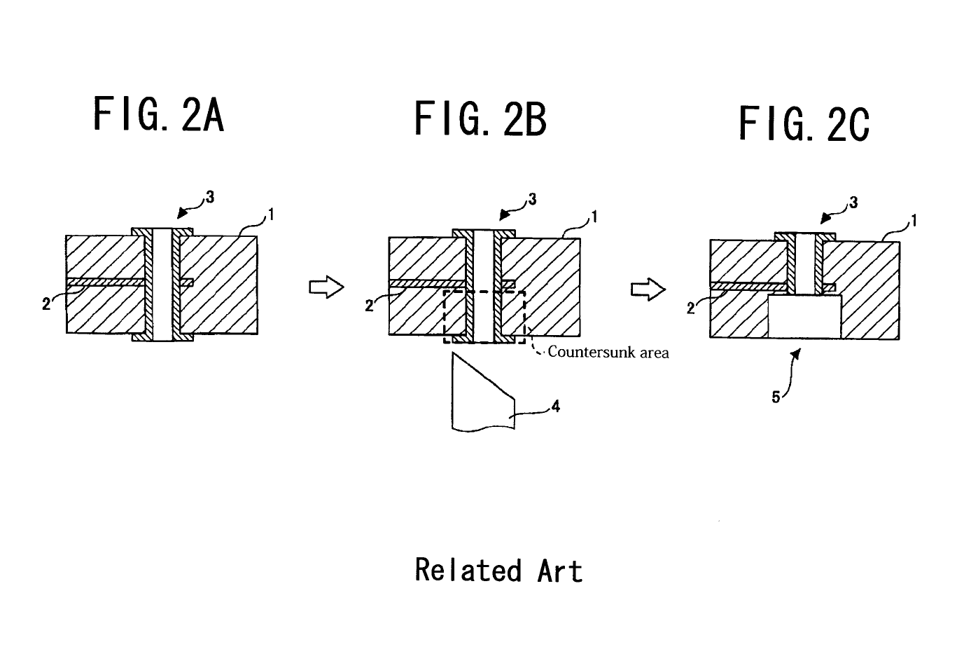

After the marking 30 is formed, the back-drilled hole 20 is formed in the position of the plated through hole 14 having a stub to remove. The back-drilled hole 20 is formed by the process shown in FIG. 2. A stub in the plated through hole 14, e.g., a signal path of high-frequency signals or high-speed signals, which may be adversely affected by the existence of a stub, should be removed.

The above-described formation process of the marking 30 and formation process of the back-drilled hole 20 are performed within a manufacture process of the wiring board 10A.

After the back-drilled hole 20 is formed, a test is performed to determine whether or not a bad back-drill occurs. This test can easily determine whether or not a bad back-drill occurs. That is, the test can determine the removing state of the plated through hole 14 by visually checking how much of the marking 30 remains on the wiring board.

As described above, in the present embodiment, the marking 30 in a color having a high level of visibility is provided in the position where the back-drill hole 20 is formed. Due to this, a part of the marking 30 remains on top of the wiring board 10A if the formation position of the back-drilled hole 20 is out of the desired position. Thus, it is possible to check easily and visually the misalignment of the back-drilled hole 20. Therefore, the present embodiment can easily determine that the part corresponding to a stub in the plated through hole 14 remains, and can properly respond such as restarting a back-drill immediately.

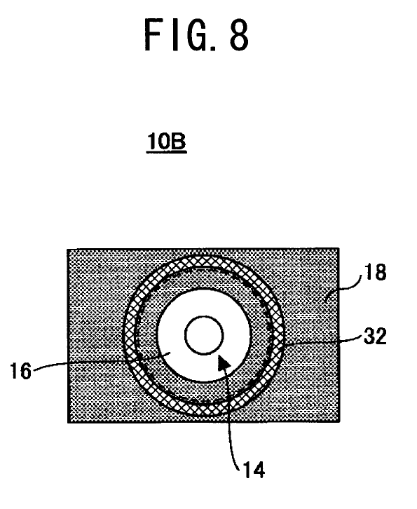

Next, a second embodiment is explained using FIG. 8. FIG. 8 discloses that a marking 32 having an annulus ring shape is printed outside of the area where the back-drilled hole 20 should be formed. After the back-drilled hole 20 is formed, the marking 32 is formed as an indicator to check visually the position of the back-drilled hole 20. In FIG. 8, the inside of the dotted line circle is shown as the area where the back-drilled hole 20, i.e., a countersunk area, should be formed. The dotted line circle showing the countersunk area is presented to explain for convenience sake of drawing, but is actually not drawn on top of the wiring board 10B. The dotted line circle has almost the same shape as the external diameter of the back-drilled hole 20. However, the dotted line circle is presented as a circle whose diameter is slightly bigger than the external diameter of the back-drilled hole 20 for convenience sake of drawing.

The marking 32 is a printed part having an annulus ring shape whose internal diameter is slightly bigger than the countersunk area, and is formed on top of the solder resist 18. The solder resist 18 is generally dark green. Thus, it is preferable that the marking 32 has a color such as white or deep light blue to be visually distinguishable from the color of the solder resist 18.

The marking 32 can be formed by printing a color ink such as white ink or deep light blue ink using a silk-screen printmaking process. The marking 32 also can be formed by various processes such as ink-jet.

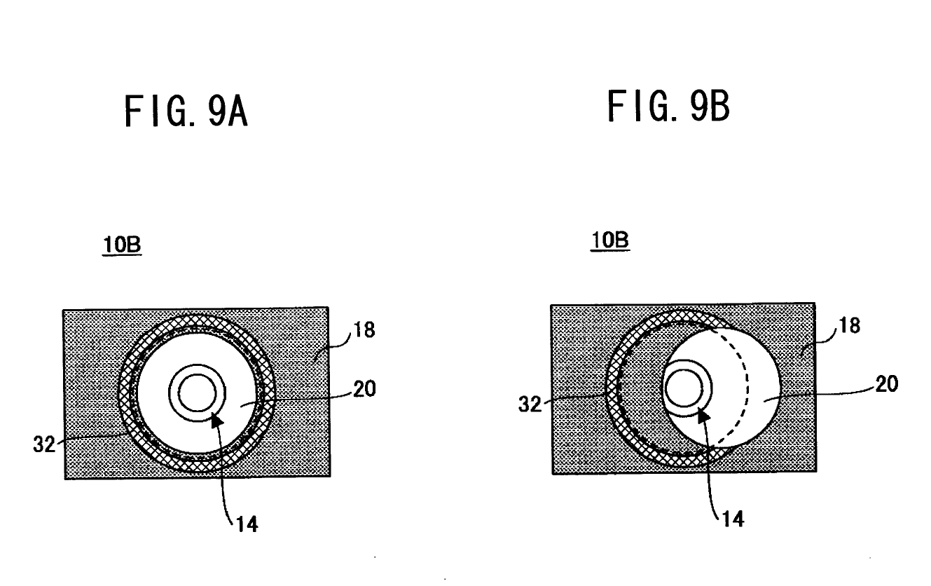

The back-drilled hole 20 is formed after the marking 32 is formed. Due to this, a part of the plated through hole 14 is removed. The internal diameter of the marking 32 is set to the same as the external diameter of the back-drilled hole 20, or is set to be slightly bigger than the external diameter of the back-drilled hole 20. Therefore, if the drill is correctly positioned at the position of the drill when the back-drilled hole 20 is formed, that is, if the drill is positioned with accuracy and the position of the back-drilled hole 20 is not out of the countersunk area, the whole marking 32 remains on top of the wiring board 10B, even after the back-drilled hole 20 is formed. This state is shown in FIG. 9A. The dotted line circle in FIG. 9A shows the countersunk area. The dotted line circle in FIG. 9B also shows the countersunk area.

On the other hand, when the drill is positioned with less accuracy and the position of the back-drilled hole 20 is considerably out of the countersunk area, a part of the marking 32 is removed as shown in FIG. 9B. In this case, a part of the plated through hole 14 remains unremoved because the position of the back-drilled hole 20 is considerably out of the plated through hole 14. FIG. 9B shows that a part of the plated through hole 14 is out of the back-drilled hole 20. FIG. 9B shows that a part of the plated through hole 14 seen at the bottom of the back-drilled hole 20 is out of the back-drilled hole 20. The part outside of the plated through hole 14 remains unremoved. This state shows that the stub is not completely removed and a bad back-drill occurs. Therefore, it is possible to determine that a bad back-drilled occurs when the remaining part of the marking 32 can be seen visually and easily after the back-drilled hole 20 is formed. Since the marking 32 is formed in a color having a high level of visibility, it is possible to determine visually whether or not the part of the marking 32 is removed, or how much of the marking 32 remains. That is, the present embodiment can determine easily and visually whether or not a bad back-drill occurs by forming the marking 32.

It is preferable to decide on an external diameter of the marking 32 in consideration of the external diameter of the plated through hole 14. It is preferable to decide on an external diameter of the marking 32 so as to check easily and visually that the entire circumference of the marking 32 remains when the back-drilled hole 20 is out of the desired position, and the external diameter of the back-drilled hole 20 does not exceed the external diameter of the plated through hole 14. If the external diameter of the marking 32 is too small, the back-drilled hole 20 exceeds the external diameter of the marking 32 when the back-drilled hole 20 is slightly out of position. This may be considered a bad back-drill by mistake even though the misalignment of the plated through hole 20 is within the accepted range. On the contrary, if the external diameter is too big, the entire circumference of the marking 32 remains even if the part of the plated through hole 14 remains. Thus, it may not be able to determine whether or not a bad-back drill occurs even though a bad back-drill actually occurs.

The formation process of the marking 32 is the same as that of marking 30 according to the first embodiment. Thus, the explanation of the formation process of the marking 32 is omitted.

In the present embodiment, the marking 32 in a color having a high level of visibility is formed as an indicator outside of the position where the back-drilled hole 20 is formed. Due to this, a part of marking 32 is removed if the formation position of the back-drilled hole 20 is out of the desired position. Thus, the misalignment of the back-drilled hole 20 can be checked easily and visually. Therefore, it is possible to easily determine that a part of the plated through hole 14 remains due to the misalignment of the back-drilled hole 20, and properly respond such as restarting a back-drill immediately.

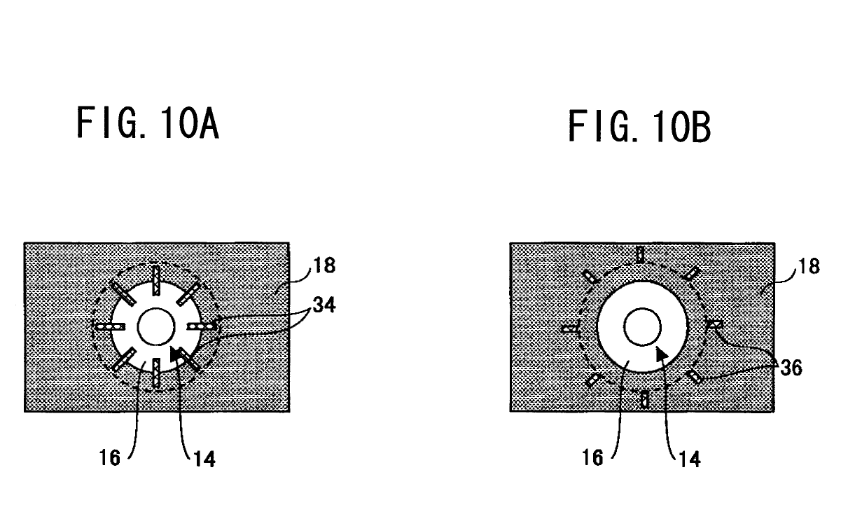

FIG. 10A discloses an example of a plurality of markings 34, instead of the marking 30, which are allocated continuously at even intervals in the annulus ring shaped area. FIG. 10B discloses an example of a plurality of markings 36, instead of the marking 32, which are allocated continuously at even intervals in the annulus ring shaped area. As with the first embodiment and the second embodiment, these deformation examples can visually determine the misalignment of the back-drilled hole 20, by allocating a plurality of the markings at even intervals in the annulus ring shaped area.

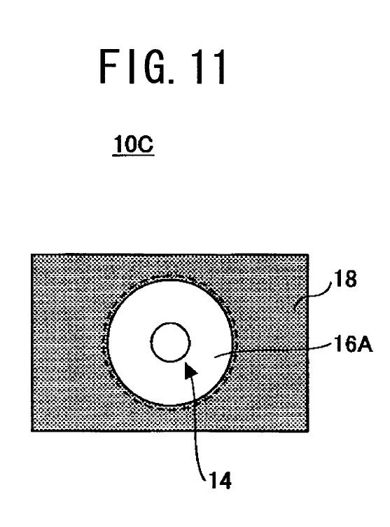

A third embodiment is explained using FIG. 11. In the present embodiment, a land 16A which is bigger than a normal land is formed as an indicator instead of the marking 30 according to the first embodiment. In FIG. 11, the land 16A as an indicator is formed into almost the same size as the countersunk area shown with a dotted line circle. The land 16A should be removed with the back-drill. Also, the land 16A may be bigger than a normal land because the land 16A does not have to operate as a normal land.

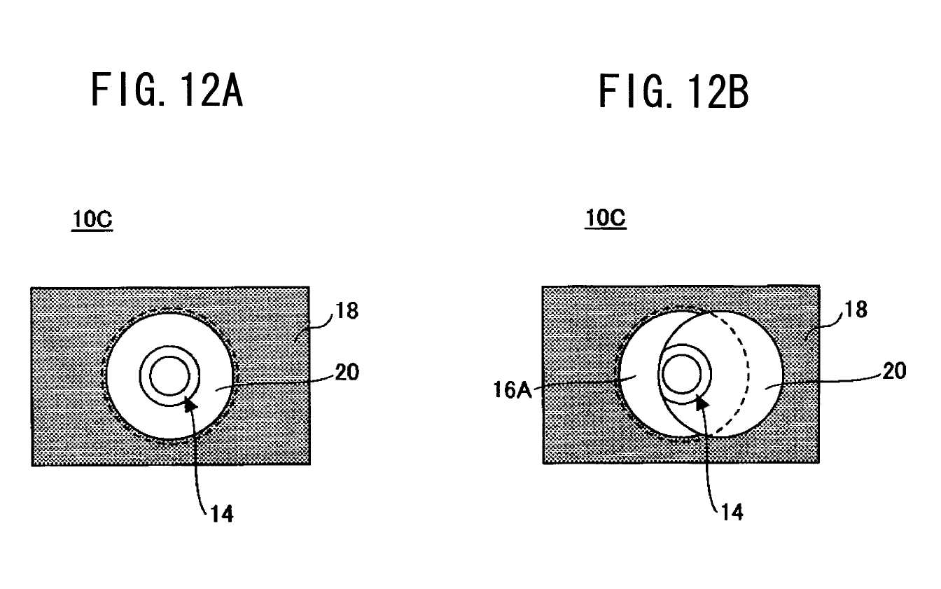

The external diameter of the land 16A is set to the same as the external diameter of the back-drilled hole 20, or is set to be slightly smaller than the external diameter of the back-drilled hole 20. Therefore, when forming the back-drilled hole 20, if the drill is correctly positioned at the countersunk area, that is, if the drill is positioned with accuracy and the position of the back-drilled hole 20 is not out of the countersunk area, the land 16A is entirely removed with the drill. Accordingly, the land 16A is removed and cannot be seen after the back-drilled hole 20 is formed. This state is shown in FIG. 12A. The dotted line circle in FIG. 12A shows the countersunk area. The dotted line circle in FIG. 12B also shows the countersunk area.

On the other hand, when the drill is positioned with less accuracy and the position of the back-drilled hole 20 is considerably out of the countersunk area, a part of the land 16A remains unremoved, as shown in FIG. 12B. This case shows that a part of the land 16A remains because the position of the back-drilled hole 20 is considerably out of the plated through hole 14. In FIG. 12B, the part of the plated through hole 14 seen at the bottom of the plated through hole 14 is out of the back-drilled hole 20. The misalignment of the plated through hole 14 remains unremoved. This state shows that the stub is not completely removed and a bad-back drill occurs. Therefore, it is possible to determine that a bad aback-drill occurs when the remaining part of the land 16A can be seen after the back-drilled hole 20 is formed. The land 16A is formed from metal such as copper, thereby having a high level of visibility. Accordingly, it is possible to check easily and visually whether or not the land 16A remains. It is possible to determine easily and visually whether or not a bad back-drill occurs by forming the land 16A.

It is preferable to decide on an external diameter of the land 16A in consideration of the external diameter of the plated through hole 14. That is, it is preferable to decide on an external diameter of the land 16A so as to check easily and visually the remaining part of the land 16A when the external diameter of the back-drilled hole 20 does not exceed the external diameter of the plated through hole 14. If the external diameter of the land 16A is too small, the visibility of the land 16A is low even if the part of the plated through hole 14 remains. On the contrary, if the external diameter of the land 16A is too big, the remaining part of the land 16A is big and the visibility of the land 16A is too high when the back-drilled hole 20 is slightly out of the desired position. Thus, this may be considered a bad back-drill by mistake, even though the misalignment of the plated through hole 20 is within the accepted range.

The present embodiment does not need to add a special process so as to form the land 16A before the back-drilled hole is formed because the land 16A is formed by a process such as plating within the formation process of the plated through hole 14.

In the present embodiment, the land 16A having a high level of visibility is provided as an indicator over almost the entire area where the back-drilled hole 20 is formed. Due to this, it is possible to easily check the misalignment of the back-drilled hole 20 even if the formation position of the back-drilled hole 20 is out of the desired position because the part of the land 16A remains on top of the wiring board 10A. Accordingly, the present embodiment can easily determine that the part of the plated through hole 14 remains due to the misalignment of the back-drilled hole 20, and can also properly respond such as restarting a back-drill immediately.

What is claimed is:

1. A wiring board, comprising:
a plated through hole provided on the wiring board; and
an indicator provided around the plated through hole, indicating a processing state related to the plated through hole.

2. The wiring board according to claim 1, wherein the indicator has an annulus ring shape and comprises a central axis corresponding to a central axis of the plated through hole, and a circumference of the indicator having the annulus ring shape is included in a countersunk area where the plated through hole is removed.

3. The wiring board according to claim 1, wherein the indicator is a pattern formed with coloring materials.

4. The wiring board according to claim 1, wherein the indicator comprises an internal axis corresponding to an internal axis of the plated through hole, and a circumference of the indicator has a plurality of patterns continuously provided in an annulus ring-shaped area included in a countersunk area where the plated through hole is removed.

5. The wiring board according to claim 1, wherein the indicator comprises an internal axis corresponding to an internal axis of the plated through hole, and an annulus ring shape whose internal diameter is bigger than a countersunk area where the plated through hole is removed.

6. The wiring board according to claim 5, further comprising a processing hole formed in a position where the plated through hole is formed, and the plated through hole is exposed at a bottom.

7. The wiring board according to claim 1, wherein the indicator comprises an internal axis corresponding to an internal axis of the plated through hole, and an inner circumference has a plurality of patterns continuously provided in an annulus ring-shaped area whose diameter is bigger than a countersunk area where the plated through hole is removed.

8. The wiring board according to claim 1, wherein the indicator is a pattern of conductive materials.

9. The wiring board according to claim 8, wherein the pattern of conductive materials is formed into one pattern with the same material as that of the plated through hole.

10. A method of manufacturing a wiring board, the method comprising:
forming a plated through hole in the board;
forming an indicator around the plated through hole on a surface of the board, the indicator can be checked visually; and
forming a processing hole by removing a part of the plated through hole in the indicator together with the wiring board nearby.

11. The method of manufacturing a wiring board according to claim 10, wherein the forming the processing hole comprises removing at least a portion of the indicator, and the method further comprising:
checking a level of remaining indicator after the indicator is removed during forming the processing hole; and
determining a removing state of the plated through hole by the result of the checking.

12. The method of manufacturing a wiring board according to claim 10, wherein the forming the indicator comprises forming the indicator as a pattern formed with coloring materials.

13. The method of manufacturing a wiring board according to 10, wherein the forming the indicator and the forming the plated through hole are performed at the same time.

14. The method of manufacturing a wiring board according to claim 10, wherein the forming the indictor comprises forming a pattern of conductive materials into one with the same material as that of the plated through hole.
